(19) United States
(12) Patent Application Publication
(10) Pub. No.: US 2025/0132254 A1
(43) Pub. Date: Apr. 24, 2025

(54) SEMICONDUCTOR STRUCTURES AND METHODS WITH REDUCED PLASMA INDUCED DAMAGE

(71) Applicant: Taiwan Semiconductor Manufacturing Company, Ltd., Hsin-Chu (TW)

(72) Inventor: Yung-Shih Cheng, Hsinchu City (TW)

(21) Appl. No.: 18/492,359

(22) Filed: Oct. 23, 2023

(51) Int. Cl. H01L 23/528; H01L 21/3065; H01L 27/088; H01L 29/06; H01L 29/40; H01L 29/417; H01L 29/423; H01L 29/775; H01L 29/786; H01L 29/861

(52) U.S. Cl. CPC H01L 23/5286; H01L 21/3065; H10D 8/411; H10D 30/43; H10D 30/6735; H10D 30/6757; H10D 62/121; H10D 64/01; H10D 64/254; H10D 84/83

(57) ABSTRACT

A method includes attaching a second workpiece to a first workpiece, performing a first plasma etching process to a back side of the first workpiece to form a first trench, and forming a first backside conductive feature in the first trench. The first workpiece includes a first transistor including a source/drain (S/D) feature, a second transistor adjacent to the first transistor and comprising a gate structure, a diode, and an interconnect structure including a plurality of metal lines and vias. A first interconnect layer of the interconnect structure includes a metal line electrically coupled to the gate structure and the S/D feature. The second workpiece includes a first dielectric layer, a metal feature extending through the first dielectric layer, and a carrier substrate disposed over the first dielectric layer. The metal feature is electrically coupled to the gate structure by the diode and the plurality of metal lines and vias.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As feature sizes continue to decrease, some IC features such as source/drain metal contacts and power line connections may be formed on a backside of a semiconductor substrate. This allows for better spacing management while optimizing power consumption. However, when forming the backside vias and power line connections, charge accumulation during etching processes can damage the integrated circuit device. Accordingly, although existing semiconductor structures have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a semiconductor structure according to various aspects of the present disclosure.

FIG. 2 is a top view of a workpiece, in portion or entirety, during various stages of the method of FIG. 1, according to various aspects of the present disclosure.

FIG. 3 illustrates a cross-sectional view of the workpiece taken along line C-C′ shown in FIG. 2, in portion or entirety, during various stages of the method of FIG. 1, according to various aspects of the present disclosure.

FIGS. 4, 5, and 6 illustrate cross-sectional views of portions of the workpiece taken along line A-A′ and line B-B′ shown in FIG. 2, during various stages of the method of FIG. 1, according to various aspects of the present disclosure.

FIGS. 7, 8, and 9 illustrate cross-sectional views of a carrier piece, in portion or entirety, during various stages of the method of FIG. 1, according to various aspects of the present disclosure.

FIGS. 10, 11, 12, 13, 14, 15, and 16 illustrate cross-sectional views of the workpiece and the carrier piece taken along line A-A′ and line B-B′ shown in FIG. 2, in portion or entirety, during various stages of the method of FIG. 1, according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Multi-gate devices, such as fin field-effect transistors (FinFETs) and multi-bridge-channel (MBC) transistors, have been introduced in an effort to improve gate control by increasing gate-channel coupling, reduce OFF-state current, and reduce short-channel effects (SCEs). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, or other nanostructures and for those reasons, an MBC transistor may also be referred to as a nanostructure transistor.

Conventionally, multi-gate devices (e.g., FinFETs and GAA devices) are built in a stacked-up fashion, having transistors at the lowest level and interconnect (vias and wires) on top of the transistors to provide connectivity to the transistors. Power rails (such as metal lines for voltage sources and ground planes) are also above the transistors and may be part of the interconnect. As the integrated circuits continue to scale down, so do the power rails. This inevitably leads to increased voltage drop across the power rails, as well as increased power consumption of the integrated circuits. One area of interest is how to form power rails and vias on the back side of an IC with reduced resistance and reduced coupling capacitance. This increases the number of metal tracks available in the structure for directly connecting to source/drain contacts and vias. It also increases the gate density for greater device integration than existing structures without the backside power rails. The backside power rails may have wider dimension than the first level metal (M0) tracks on the frontside of the structure, which beneficially reduces the power rail resistance.

Plasma treatment (e.g., plasma etching processes) may be used to form backside power rails and vias and may cause plasma induced damage (PID) to occur in the previously formed multi-gate devices, thereby causing channel resistance degradation, threshold voltage shift, circuit leakage, failed device yield, and/or reduced device reliability. Therefore, although existing semiconductor structures have been generally adequate for their intended purposes, they have not been entirely satisfactory in all respects.

The present disclosure provides semiconductor structures and methods of making the same with reduced plasma induced damage (PID). In some embodiments, a method disclosed herein includes providing a workpiece and a carrier piece, attaching the carrier piece over the workpiece, performing a plasma etching process to a back side of the workpiece to form a trench, and forming a backside conductive feature in the trench. The workpiece may include a diode, a first transistor including a source/drain (S/D) feature, a second transistor including a metal gate structure, and an interconnect structure disposed thereover. The carrier piece may include a carrier substrate, a bonding layer, and a metal feature through the bonding layer. After attaching the workpiece and the carrier piece, the metal feature is electrically coupled to frontside conductive features of the interconnect structure. As such, an electrical connection (or a conductive path) is formed between the metal gate structure and the metal feature. Therefore, electrical charges induced by the plasma etching process may be released through the conductive path rather than being accumulated around or even flowing into a gate dielectric layer of the metal gate structure of the second transistor, thus PID caused by the electrical charges may be advantageously reduced or even eliminated.

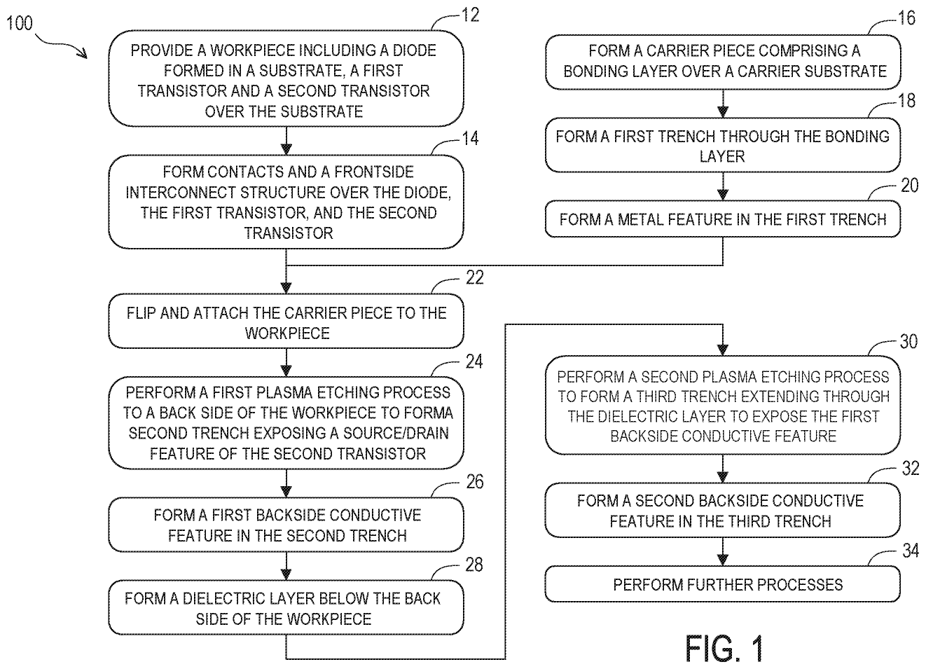

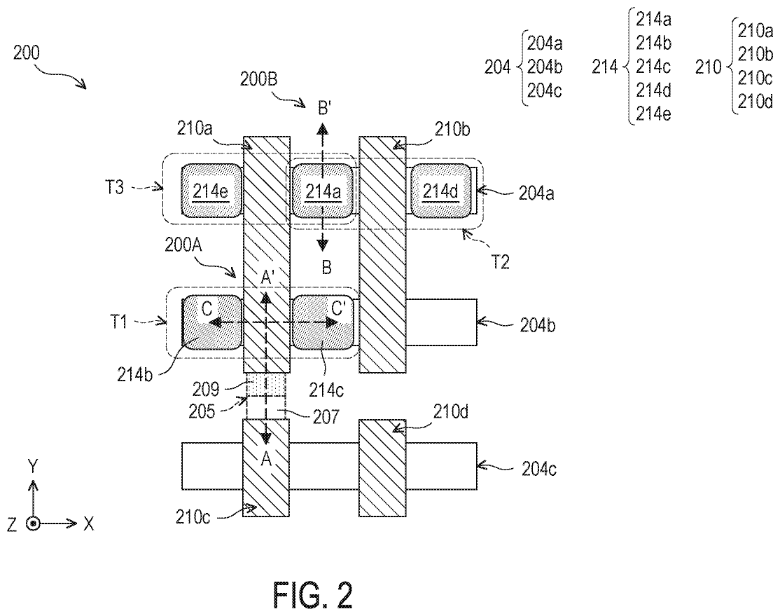

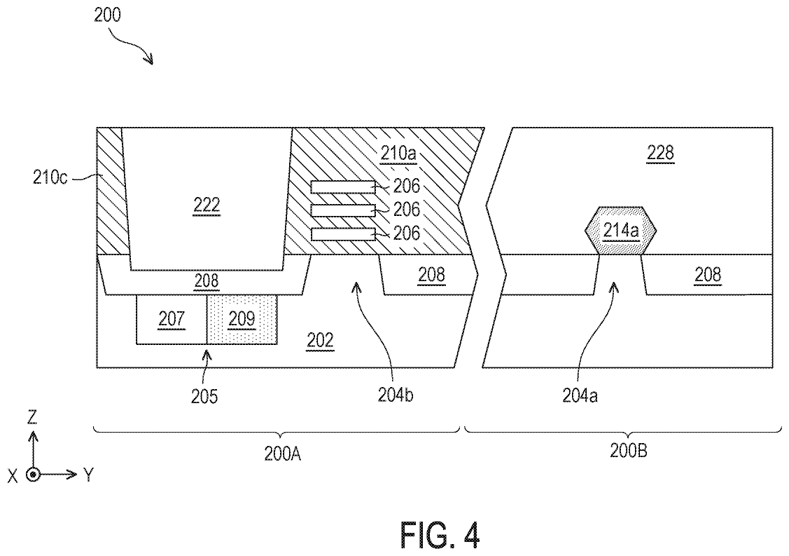

The various aspects of the present disclosure will now be described in more detail with reference to the figures. In that regard, FIG. 1 is a flow chart of a method 100 for fabricating a semiconductor structure 400 according to various aspects of the present disclosure. Method 100 is described below in conjunction with FIGS. 2-16, which are fragmentary top or cross-sectional views of a workpiece 400 (including a workpiece 200 and a carrier piece 300) at different stages of fabrication according to embodiments of method 100. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. For the purpose of simplicity, portions of the workpiece 400 taken along line A-A′ and line B-B′ are referred to as region 200A and region 200B, respectively. Although the region 200A and the region 200B may not be in a same plane, they are both illustrated in FIGS. 4-6 and 10-16. Because the workpiece 400 will be fabricated into a semiconductor structure upon conclusion of the fabrication processes, the workpiece 400 may be referred to as the semiconductor structure 400 as the context requires. For avoidance of doubts, the X, Y and Z directions in FIGS. 2-16 are perpendicular to one another and are used consistently throughout the present disclosure. Throughout the present disclosure, like reference numerals denote like features unless otherwise excepted.

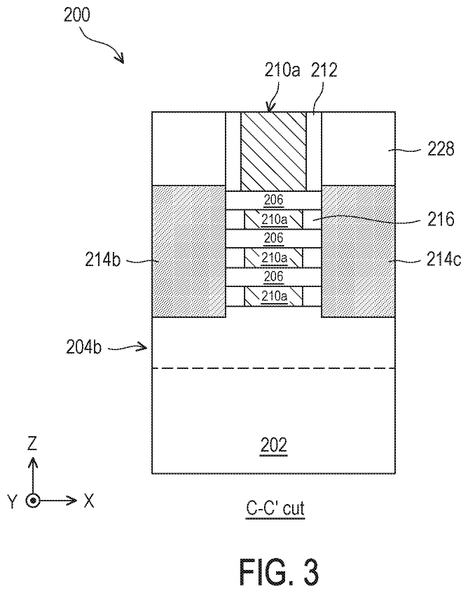

Referring to FIGS. 1-4, method 100 includes a block 12 where a workpiece 200 is provided. FIG. 2 is a top view of the workpiece 200, in portion or entirety, to undergo various stages of operations in the method 100 of FIG. 1, according to various aspects of the present disclosure. FIG. 3 illustrates a cross-sectional view of the workpiece 200 taken along line C-C′ shown in FIG. 2. FIG. 4 illustrates cross-sectional views of regions 200A and 200B of the workpiece 200 taken along line A-A′ and line B-B′ shown in FIG. 2, respectively.

As illustrated in FIGS. 2-4, the workpiece 200 includes a substrate 202. In one embodiment, the substrate 202 may be a silicon (Si) substrate. In some other embodiments, the substrate 202 may include other semiconductor materials such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs).

In embodiments, the workpiece 200 includes a number of active regions (e.g., active regions 204a, 204b, 204c) protruding from the substrate 202. The active regions 204a, 204b, 204c may be individually or collectively referred to as the active regions 204 dependent upon the context. As depicted in FIG. 2, each of the active regions 204 extends lengthwise along the X direction. The active regions 204 may have a fin-shaped structure and thus be referred to as fins 204. The number of the active regions 204 shown in FIG. 2 are for illustration purpose only and should not be construed as limiting the scope of the present disclosure. In embodiments represented by FIGS. 2 and 3, the workpiece 200 includes MBC transistors (e.g., transistors T1, T2, and T3 as shown in FIG. 2), and the active regions 204 include a stack of semiconductor layers 206 (shown in FIG. 3) suspended between each pair of source/drain features (e.g., source/drain features 214a, 214b, 214c, 214d, and 214e). The source/drain features 214a, 214b, 214c, 214d, and 214e may be individually or collectively referred to as the source/drain features 214 dependent upon the context. The stack of semiconductor layers 206 serve as the transistor channels for the MBC transistors. Accordingly, the semiconductor layers 206 are also referred to as channel layers 206. Each of the channel layers 206 may be formed of silicon (Si) (e.g., single crystalline silicon). Alternatively, the channel layers 206 may comprise germanium, silicon germanium, or another suitable semiconductor material(s). Initially, the channel layers 206 are formed as part of a semiconductor layer stack that includes the channel layers 206 and other semiconductor layers (e.g., sacrificial layers) of a different material. As part of the process of forming the active regions 204, the semiconductor layer stack is also patterned into fins protruding above the substrate 202. During a gate replacement process, the semiconductor layer stack is selectively etched to remove the other semiconductor layers, leaving the channel layers 206 suspended over the substrate 202 and between the respective source/drain features 214. This is also referred to as a channel release process.

In the present embodiments, the workpiece 200 also includes an isolation feature 208 (shown in FIG. 4) formed around each active region 204 to isolate two adjacent active regions 204. The isolation feature 208 may also be referred to as a shallow trench isolation (STI) feature and may include silicon oxide, silicon oxynitride, fluorine-doped silicate glass (FSG), a low-k dielectric, combinations thereof, and/or other suitable materials.

In embodiments, the workpiece 200 includes metal gate structures (e.g., metal gate structures 210a, 210b, 210c, and 210d) disposed over and wrapping around the channel layers 206 of channel regions of the active regions 204, and extend lengthwise along the Y direction. The metal gate structures 210a, 210b, 210c, and 210d may be individually or collectively referred to as the metal gate structures 210 dependent upon the context. The number of the metal gate structures 210 shown in FIG. 2 are for illustration purpose only and should not be construed as limiting the scope of the present disclosure. In the depicted embodiment, the metal gate structure 210a has a first portion interposing the source/drain features 214b and 214c and a second portion interposing the source/drain features 214a and 214e, and the metal gate structure 210b has a portion interposing the source/drain features 214a and 214d. In the depicted embodiment, the metal gate structures 210c and 210d are disposed over the active region 204c. The metal gate structures 210a and 210c may be formed from separating a continuous metal gate structure into two portions by a gate isolation structure 222 (to be described below). The gate isolation structure 222 may be also configured to provide electrical and physical isolation between the metal gate structures 210b and 210d. The metal gate structures 210 each includes a high-k dielectric layer (i.e., having a dielectric constant greater than that of silicon oxide, which is about 3.9; not depicted) disposed over the active regions 204 and a metal gate electrode (not depicted) disposed over the high-k dielectric layer. The metal gate electrode may further include at least one work function metal layer disposed over the high-k dielectric layer and a bulk conductive layer disposed thereover. The work function metal layer may be a p-type or an n-type work function metal layer. Example work function materials include TiN, TaN, WN, ZrSi₂, MoSi₂, TaSi₂, NiSi₂, Ti, TaAl, TaAIC, TiAlN, TaC, TaCN, TaSiN, other suitable work function materials, or combinations thereof. The bulk conductive layer may include copper (Cu), tungsten (W), aluminum (Al), cobalt (Co), other suitable materials, or combinations thereof. The metal gate structures 210 may further include numerous other layers (not depicted), such as an interfacial layer disposed between the active regions 204 and the high-k dielectric layer, hard mask layers, capping layers, barrier layers, other suitable layers, or combinations thereof. Various layers of the metal gate structures 210 may be deposited by any suitable method, such as chemical oxidation, thermal oxidation, atomic layer deposition (ALD), chemical vapor deposition (CVD), physical vapor deposition (PVD), plating, other suitable methods, or combinations thereof. A polishing process, such as a chemical mechanical planarization/polishing (CMP) process, may be performed to remove excess materials from a top surface of the metal gate structures 210 to planarize a top surface of the workpiece 200.

In some embodiments, the metal gate structures 210 are formed after other components of the workpiece 200 (e.g., the source/drain features 214) are fabricated. Such process is generally referred to as a gate replacement process, which includes forming dummy gate structures (not depicted) as a placeholder for the metal gate structures 210, forming the source/drain features 214, forming dielectric structure 228 over the dummy gate structures and the source/drain features 214, planarizing the dielectric structure 228 by, for example, CMP, to expose top surfaces of the dummy gate structures, removing the dummy gate structures in the dielectric structure 228 to form trenches that expose the channel regions of the active regions 204, removing the sacrificial layers for channel release, and forming the metal gate structures 210 in the trenches and around the channel layers 206 to complete the gate replacement process. Although not shown, in some embodiments, the metal gate structure 210 may be partially recessed, and a dielectric cap layer may be formed on the recessed metal gate structure 210.

In embodiments, the workpiece 200 further includes gate spacers 212 (shown in FIG. 3) disposed on sidewalls of the metal gate structures 210. The gate spacers 212 may include a dielectric material, such as an oxygen-containing material (e.g., silicon oxide, silicon oxycarbide, aluminum oxide, aluminum oxynitride, hafnium oxide, titanium oxide, zirconium aluminum oxide, zinc oxide, tantalum oxide, lanthanum oxide, yttrium oxide, silicon oxycarbonitride, etc.), a nitrogen-containing material (e.g., tantalum carbonitride, silicon nitride (SiN), zirconium nitride, silicon carbonitride, etc.), a silicon-containing material (e.g., hafnium silicide, silicon, zirconium silicide, etc.), other suitable materials, or combinations thereof. The gate spacers 212 may be a single layered structure or a multi-layered structure. Notably, the composition of the gate spacers 212 is distinct from that of the surrounding dielectric components (e.g., the dielectric structure 228), such that an etching selectivity may exist between the gate spacers 212 and the surrounding dielectric components during subsequent etching processes. In an embodiment, the gate spacers 212 include SiN. The gate spacers 212 may be formed by first depositing a blanket of spacer material over the workpiece 200, and then performing an anisotropic etching process to remove portions of the spacer material to form the gate spacers 212.

In some embodiments, the workpiece 200 includes the source/drain features 214 formed in and/or over source/drain regions of the active regions 204, each being disposed adjacent to the metal gate structure 210a and/or the metal gate structure 210b. The source/drain feature(s) 214 may refer to a source or a drain, individually or collectively dependent upon the context. In embodiments, the source/drain feature 214a is a source feature. The source/drain features 214 may be formed by any suitable techniques, such as etching processes followed by one or more epitaxial growth processes. In one example, one or more etching processes are performed to remove portions of the active regions 204 to form recesses (not shown) in the source/drain regions. A cleaning process may be performed to clean the recesses with a hydrofluoric acid (HF) solution or other suitable solution. Subsequently, one or more epitaxial growth processes are performed to grow the source/drain features 214 in the recesses. Each of the source/drain features 214 may be suitable for forming a p-type FinFET device or alternatively, an n-type FinFET device. The p-type source/drain features may include one or more epitaxial layers of silicon germanium (epi SiGe) doped with a p-type dopant such as boron, germanium, indium, and/or other p-type dopants. The n-type source/drain features may include one or more epitaxial layers of silicon (epi Si) or silicon carbon (epi SiC) doped with an n-type dopant such as arsenic, phosphorus, and/or other n-type dopant.

In some embodiments, the workpiece 200 further includes inner spacers 216 (shown in FIG. 3) between the S/D features 214 and the metal gate structures 210. In some embodiments, the inner spacers 216 include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the inner spacers 216 include a low-k dielectric material, such as those described herein. The inner spacers 216 may be formed by deposition and etching processes. For example, after S/D trenches are etched and before the S/D features 214 are epitaxially grown from the S/D trenches, an etch process may be used to recess the sacrificial layers between the adjacent channel layers 206 to form gaps vertically between the adjacent channel layers 206. Then, one or more dielectric materials are deposited (using CVD or ALD for example) to fill the gaps. Another etching process is performed to remove the dielectric materials outside the gaps, thereby forming the inner spacers 216.

In some embodiments, the dielectric structure 228 is disposed over the source/drain features 214 and may include a contact etch-stop layer (CESL) and an interlayer dielectric (ILD) layer formed over the CESL. The ILD layer includes a dielectric material, such as tetraethylorthosilicate (TEOS), silicon oxide, a low-k dielectric material, doped silicon oxide such as borophosphosilicate glass (BPSG), phosphosilicate glass (PSG), FSG, boron doped silicate glass (BSG), other suitable dielectric materials, or combinations thereof. The ILD layer may include a multi-layer structure having multiple dielectric materials and may be formed by a deposition process such as, for example, CVD, flowable CVD (FCVD), spin-on-glass (SOG), other suitable methods, or combinations thereof. The CESL may comprise silicon nitride, silicon oxynitride, silicon nitride with oxygen or carbon elements, other suitable materials, or combinations thereof, and may be formed by CVD, PVD, ALD, other suitable methods, or combinations thereof. The ILD layer may be deposited after the deposition of the CESL.

In embodiments, the workpiece 200 includes a diode (e.g., a P/N junction) 205 (shown in FIGS. 2 and 4) disposed in and/or on the substrate 202. The diode 205 may be any suitable diode. In the present embodiments, the diode 205 is a P/N junction diode and includes a P well 207 and an N well 209 directly contacting the P well 207. In the depicted embodiment, the P well 207 and the N well 209 are side-by-side along the Y direction, and the N well 209 is closer to the transistor T1 than the P well 207. In the depicted embodiments, a distance between the N well 209 and the metal gate structure 210a along the Y direction is greater than a distance between the P well 207 the metal gate structure 210a along the Y direction. In some other embodiments, the P well 207 and the N well 209 may be in other relative positions, such as side-by-side along another direction (e.g., the X direction), or vertically stacked together. In the depicted embodiment, the P well 207 and the N well 209 are disposed below the isolation feature 208 and between the active regions 204b and 204c. In some other embodiments, the P well 207 and the N well 209 are disposed in other positions, such as in a portion of one of the active regions 204 (e.g., the active region 204c), and/or disposed between two adjacent isolation features 208. The P well 207 may be doped with a p-type dopant, such as boron, indium, other p-type dopant, or combinations thereof. The N well 209 may be doped with an n-type dopant, such as phosphorus, arsenic, other n-type dopant, or combinations thereof. An ion implantation process, a diffusion process, and/or other suitable doping process can be performed to form the P well 207 and the N well 209.

In embodiments represented by FIG. 4, the workpiece 200 includes the gate isolation structure 222 that is disposed between and in direct contact with the metal gate structure 210a and the metal gate structure 210c along the Y direction. The gate isolation structure 222 is a dielectric feature that separates one or more long metal gate structures into short metal gate structures. In an example process, a long metal gate structure is formed in a first patterning process and then is cut into short metal gate structures 210a and 210c in a second patterning process such that the metal gate structures 210a and 210c have designed dimensions. The gate isolation structure 222 may be formed by patterning process to form trenches and deposition process to fill in the trenches with one or more dielectric materials. The patterning process includes lithography process and etching process and may use a hard mask to define the regions for the gate isolation structure 222. The etching process may include wet etch, dry etch, or a combination thereof to etch through the conductive materials of the long metal gate structure. The etching process may use one or more etchant. A CMP may be performed after the deposition process to remove the excessive materials of the gate isolation structure 222 deposited on the dielectric structure 228 and the metal gate structures 210, and planarize the top surface of the workpiece 200. The gate isolation structure 222 and the isolation feature 208 may collectively provide isolation functions-isolating the metal gate structures 210a and 210c from each other and from nearby conductors including the diode 205.

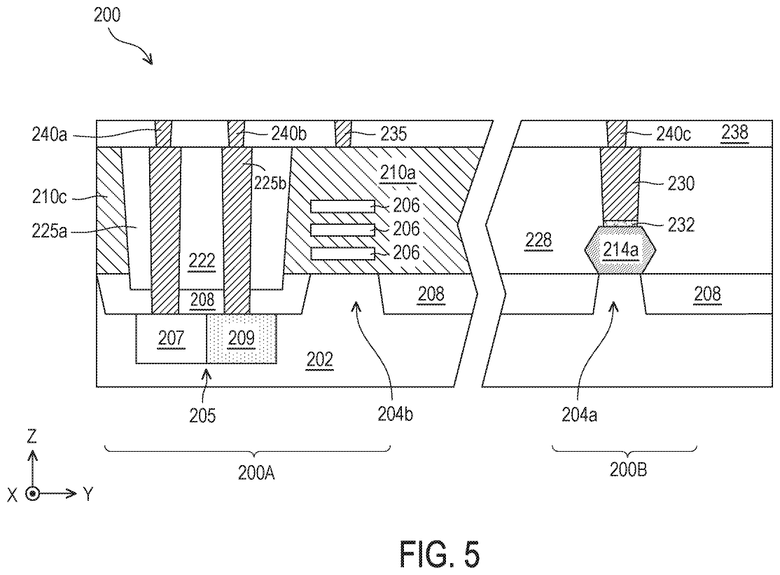

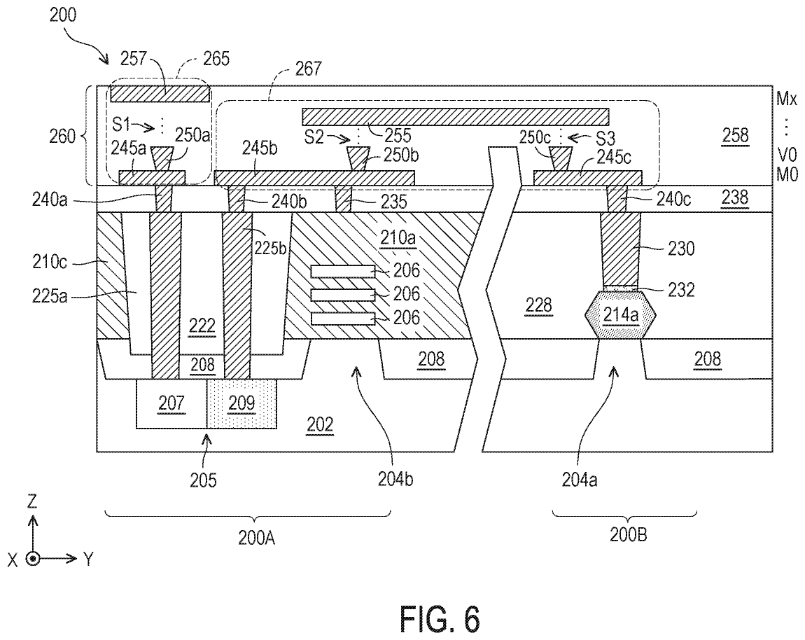

Referring to FIGS. 1 and 5-6, method 100 includes a block 14 where contacts, vias, and a frontside interconnect structure 260 are formed over the workpiece 200. FIGS. 5 and 6 illustrate cross-sectional views of the workpiece 200 taken along line A-A′ and line B-B′ shown in FIG. 2.

With respect to FIG. 5, diode contacts 225a and 225b are formed over the P well 207 and the N well 209, respectively, and a source/drain contact 230 is formed over the source/drain feature 214a. In the depicted embodiment, the source/drain contact 230 is electrically coupled to the source/drain feature 214a. In an example, an etching process is employed to remove portions of the dielectric structure 228 to form a contact trench, such that the source/drain feature 214a is exposed in the contact trench. A deposition process, such as PVD, CVD, or metal organic chemical vapor deposition (MOCVD) is then implemented to form the source/drain contact 230 over the source/drain feature 214a. A CMP process may be performed to remove excess materials and planarize the top surface. The S/D contact 230 may include tungsten (W), ruthenium (Ru), cobalt (Co), copper (Cu), titanium (Ti), titanium nitride (TiN), tantalum (Ta), tantalum nitride (TaN), molybdenum (Mo), nickel (Ni), or a combination thereof. The workpiece 200 may also include a silicide feature 232 between the source/drain contact 230 and the source/drain feature 214a to further reduce contact resistance. Forming the silicide feature 232 may include depositing one or more metals into the contact trench using CVD, PVD, ALD, or other suitable methods, performing an annealing process to the workpiece 200 to cause reaction between the one or more metals and the S/D feature 214a to produce the silicide feature 232, and removing un-reacted portions of the one or more metals, leaving the silicide feature 232 in the contact trench. The silicide feature 232 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. Alternatively, the silicide formation may be skipped and the source/drain contact 230 directly contacts the source/drain feature 214a.

In embodiments, the diode contacts 225a and 225b are electrically coupled to the P well 207 and the N well 209, respectively. In an example, an etching process is employed to remove portions of the gate isolation structure 222 and the isolation feature 208 to form contact trenches, such that the P well 207 and the N well 209 are exposed in the contact trenches, respectively. A deposition process, such as PVD, CVD, or metal organic chemical vapor deposition (MOCVD) is then implemented to form the diode contacts 225a and 225b that interfaces with the P well 207 and the N well 209, respectively. A CMP process may be performed to remove excess materials and planarize the top surface. The diode contacts 225a and 225b may include similar materials as the source/drain contact 230. The diode contacts 225a and 225b and the source/drain contact 230 may be formed simultaneously or in any suitable sequential order.

Operations in block 14 of the method 100 further includes forming a dielectric layer 238 over workpiece 200. In some embodiments, the dielectric layer 238 may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), and/or other suitable dielectric materials. The dielectric layer 238 may be deposited using plasma-enhanced CVD (PECVD), FCVD, spin-on coating, or a suitable deposition technique. In some embodiments, after formation of the dielectric layer 238, the workpiece 200 may be annealed to improve integrity of the dielectric layer 238. In some embodiments, before forming the dielectric layer 238, an etch stop layer is deposited over the workpiece 200. The formation and composition of the etch stop layer may be similar to those of the CESL of the dielectric structure 228.

After forming the dielectric layer 238, a gate via 235 is formed to electrically couple to the metal gate structure 210a, and conductive vias 240a, 240b, and 240c are formed to electrically couple to the diode contacts 225a and 225b and the source/drain contact 230, respectively. In embodiments, the gate via 235 and the conductive vias 240a, 240b, and 240c are formed to extend through the dielectric layer 238 by any suitable methods. For example, a via metal material is deposited into via trenches extending through the dielectric layer 238 with, for example, a Chemical Vapor Deposition (CVD) method, an Atomic Layer Deposition (ALD) method or the like. A CMP process is then employed to remove excess materials and planarize the top surface. Each of the gate via 235 and the conductive vias 240a, 240b, and 240c may include a conductive barrier layer and a metal fill layer over the conductive barrier layer. The conductive barrier layer functions to prevent metal materials of the metal fill layer from diffusing into the dielectric layers (e.g., the dielectric layer 238) adjacent the gate via 235 and the conductive vias 240a, 240b, and 240c. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), or other metals, and may be formed by CVD, PVD, ALD, plating, or other suitable processes. In some embodiments, the conductive barrier layer is omitted.

Referring to FIG. 6, operations in block 14 of the method 100 further includes forming the frontside interconnect structure 260 over the workpiece 200. The frontside interconnect structure 260 includes a dielectric structure 258 (e.g., a number of interlayer dielectric (ILD) layers and/or a number of etch stop layers (ESLs)) and frontside conductive features (e.g., metal lines, metal vias) disposed in the dielectric structure 258. The dielectric structure 258 may include similar dielectric materials as dielectric materials of the dielectric structure 228 and the dielectric layer 238. The frontside interconnect structure 260 may include one or more interconnect layers. In the depicted embodiment, the frontside interconnect structure 260 includes a metal zero interconnect layer M0 (M0 level), a via zero interconnect layer V0 (V0 level), . . . , and a metal x interconnect layer Mx (Mx level). Levels between the V0 level and the Mx level are not shown for simplicity. Each of the interconnect layers may be referred to as a metal level. Metal lines formed at the M0 level may be referred to as M0 metal lines (e.g., M0 metal lines 245a, 245b, and 245c). Similarly, via or metal lines formed at the V0 level, M1 level, . . . , and Mx level may be referred to as V0 vias (e.g., V0 vias 250a, 250b, and 250c), M1 metal lines, . . . , and Mx metal lines (e.g., Mx metal line 257), respectively, x may be an integer ranging from 1 to 10. Each level of the frontside interconnect structure 260 includes a layer of the frontside conductive features (e.g., metal lines, metal vias) disposed in a dielectric layer of the dielectric structure 258. In some embodiments, the frontside conductive features at a same level of the frontside interconnect structure 260, such as M0 level, are formed simultaneously. In some embodiments, frontside conductive features at a same level of the frontside interconnect structure 260 have top surfaces that are substantially planar with one another and/or bottom surfaces that are substantially planar with one another.

The frontside conductive features (e.g., metal lines, metal vias) may include copper, copper alloys, titanium, tantalum, tungsten, cobalt, molybdenum, ruthenium, or a conductive nitride such as titanium nitride, titanium aluminum nitride, tungsten nitride, tantalum nitride, or other conductive materials, or combinations thereof, and may be formed using damascene processes, dual damascene processes, chemical vapor deposition (CVD), physical vapor deposition (PVD), atomic layer deposition (ALD), and/or other suitable processes. In some embodiments, the frontside conductive features include copper (Cu). Each of the metal lines and the metal vias may include a conductive barrier layer (such as TiN or TaN) surrounding a metal core (such as copper).

The frontside conductive features electrically couples various electrical components of the workpiece 200, such as the gate via 235 and the conductive vias 240a, 240b, and 240c. In embodiments represented by FIG. 6, the gate via 235 connects the metal gate structure 210a to the M0 metal line 245b, the conductive via 240a connects the diode contact 225a to the M0 metal line 245a, the conductive via 240b connects the diode contact 225b to the M0 metal line 245b, and the conductive via 240c connects the source/drain contact 230 to the M0 metal line 245c. In some other embodiments not depicted, the gate via 235 and the conductive via 240b are not connected to a same M0 metal line; instead, they are connected by two different M0 metal lines, which are connected together by a metal line disposed at a higher level (e.g., an M1 metal line). The V0 level includes V0 vias 250a, 250b, and 250c connecting the M0 metal lines 245a, 245b, and 245c to the M1 metal lines (not depicted), respectively. In embodiments, the V0 via 250a is electrically coupled to the Mx metal line 257 by a first stack S1 of metal lines and metal vias (e.g., a combination of M1, M2, . . . , M (x-1) metal lines and V1, V2, . . . , V (x-1) vias) disposed between the V0 via 250a and the Mx metal line 257. It is noted that, the Mx metal line 257 is located at the topmost interconnect layer (the Mx level) of the frontside interconnect structure 260. In embodiments, the V0 vias 250b and 250c are electrically connected to a metal line 255 by a second stack S2 and a third stack S3 of metal lines and metal vias, respectively. The second stack S2 and the third stack S3 of metal lines and metal vias may each include M1, M2, . . . , M (x-1) metal lines and V1, V2, . . . , V (x-1) vias, or a combination of levels of metal lines and metal vias. In some embodiments, the first stack S1, the second stack S2, and the third stack S3 of metal lines and metal vias are not in direct contact with each other. In embodiments, the first stack S1, the second stack S2, and the third stack S3 of metal lines and metal vias are spaced apart from each other. The metal line 255 may be located at any one of the M1 level, M2 level, . . . , and the Mx level. In some embodiments, the Mx metal line 257 and the metal line 255 may be located at the same level or different levels. That is, the metal line 255 is located at a lower level than the Mx metal line 257 or at the same level with the Mx metal line 257. In an embodiment, the metal line 255 is located at the M1 level and in direct contact with both the V0 vias 250b and 250c.

For simplicity, the M0 metal line 245a, the V0 via 250a, the Mx metal line 257, and the first stack S1 of metal lines and metal vias are collectively referred to as a first portion 265 of the frontside conductive features as in a dashed rectangle with rounded corners on the left side of FIG. 6. The M0 metal lines 245b and 245c, the V0 vias 250b and 250c, the metal line 255, and the second stack S2 and the third stack S3 of metal lines and metal vias are collectively referred to as a second portion 267 of the frontside conductive features as in a dashed rectangle with rounded corners on the right side of FIG. 6. For the purpose of simplicity, the interconnect structure 260 above V0 level in the region 200A and the region 200B are merged. It is understood that the frontside conductive features shown in FIG. 6 may not be in a same vertical plane. For example, the Mx metal line 257 may be not vertically overlapped with M0 metal line 245a. It is understood that the conductive vias and the metal lines of the interconnect structure 260 illustrated in FIG. 6 are merely to provide a simplified example and are not meant to be limiting unless otherwise claimed.

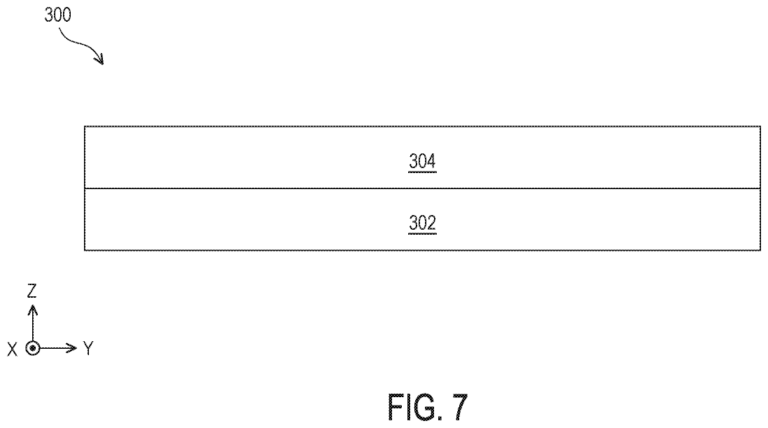

Referring to FIGS. 1 and 7, method 100 includes a block 16 where a carrier piece 300 including a carrier substrate 302 and a bonding layer 304 disposed over the carrier substrate 302 is formed. FIG. 7 illustrates a cross-sectional view of the carrier piece 300. In embodiments, the carrier substrate 302 includes a similar composition as the substrate 202, such that electrical charges may be discharged through the carrier substrate 302. In an embodiment, both the substrate 202 and the carrier substrate 302 are formed of silicon. In embodiments, the bonding layer 304 has a different material composition than the carrier substrate 302. In some embodiments, the bonding layer 304 includes a dielectric material, whereas the carrier substrate 302 includes a semiconductor material. The bonding layer 304 may include an oxide (e.g., silicon oxide or the like) that is deposited by CVD (e.g., HDP), ALD, PVD, thermal oxidation, or the like). Other suitable materials and processes may be used to form the carrier piece 300.

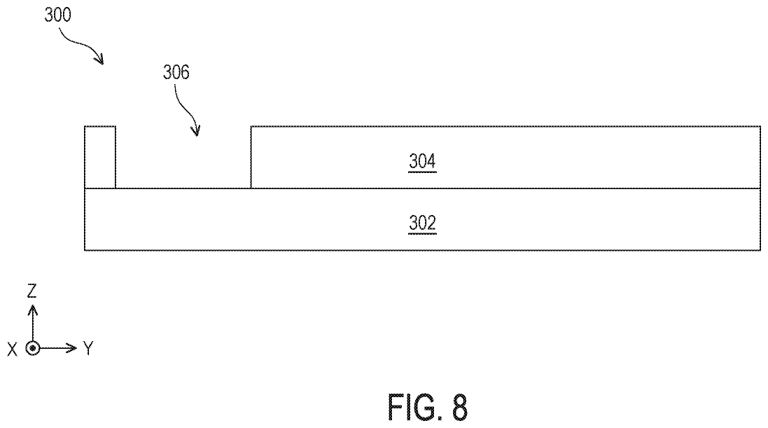

Referring to FIGS. 1 and 8, method 100 includes a block 18 where a first trench 306 is formed through the bonding layer 304. FIG. 8 illustrates a cross-sectional view of the carrier piece 300. The first trench 306 may be formed by any suitable methods. In an example, a patterning process is performed to the carrier piece 300 to form the first trench 306. The first trench 306 may stop at, and exposes, a region of the carrier substrate 302. The first trench 306 may stop at a surface of the carrier substrate 302. In some embodiments, the patterning process includes an etching process, such as a dry etching process or a wet etching process. An etching mask layer may be used during such an etching process.

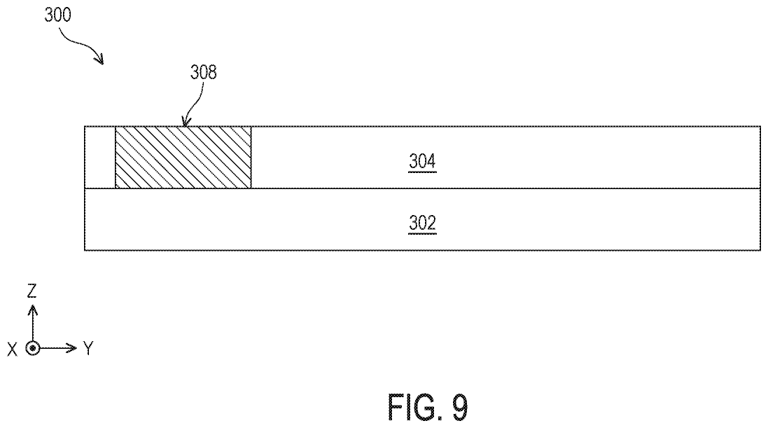

Referring to FIGS. 1 and 9, method 100 includes a block 20 where a metal feature 308 is formed in the first trench 306. FIG. 9 illustrates a cross-sectional view of the carrier piece 300. In embodiments, one or more conductive materials may be deposited over the carrier piece 300, including in the first trench 306. A CMP process is then employed to remove excess materials and planarize the top surface. The metal feature 308 may include a conductive barrier layer and a metal fill layer over the conductive barrier layer. The conductive barrier layer functions to prevent metal materials of the metal fill layer from diffusing into the dielectric layers (e.g., the bonding layer 304) adjacent the metal feature 308. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. In some embodiments, the conductive barrier layer is omitted. The metal fill layer may include tungsten (W), cobalt (Co), molybdenum (Mo), ruthenium (Ru), or other metals, and may be formed by CVD, PVD, ALD, plating, or other suitable processes. In embodiments, the metal fill layer includes Cu.

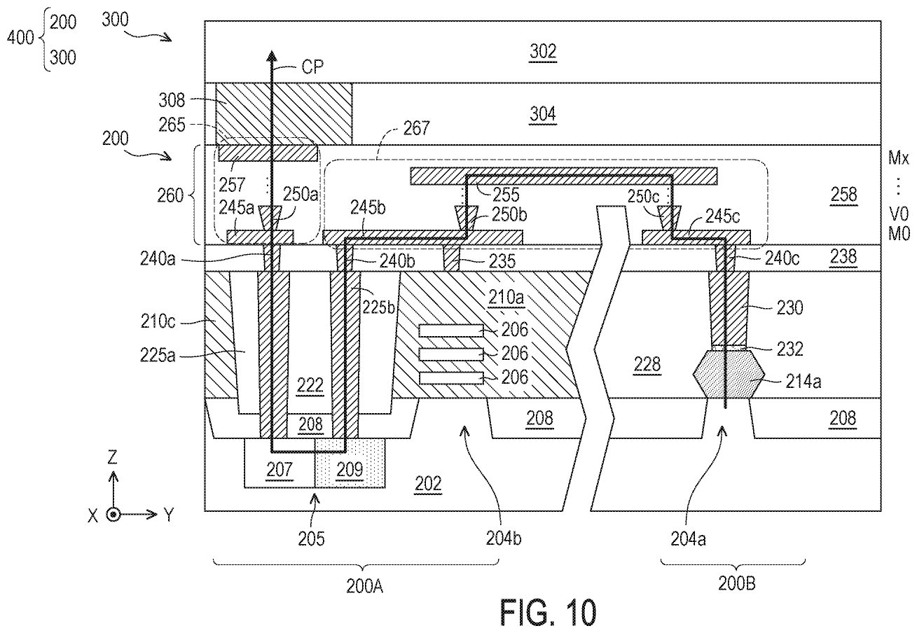

Referring to FIGS. 1 and 10, method 100 includes a block 22 where the carrier piece 300 is flipped and attached over the workpiece 200. FIG. 10 illustrates a cross-sectional view of a combination of the workpiece 200 and the carrier piece 300. For simplicity, a combination of the workpiece 200 and the carrier piece 300 may be referred to as a workpiece 400.

The bonding layer 304 bonds the carrier substrate 302 to the workpiece 200. For example, the interconnect structure 260 is bonded to the carrier substrate 302 through the bonding layer 304. Upon completion of the bonding, the Mx metal line 257 is attached and electrically coupled to the metal feature 308. In an embodiment, the Mx metal line 257 is in direct contact with the metal feature 308. Since the Mx metal line 257 is electrically coupled to the P well 207, and the N well 209 is electrically coupled to the source/drain feature 214a, a conductive path CP is formed. In embodiments, the conductive path CP is formed by the source/drain feature 214a, the source/drain contact 230, the conductive via 240c, the second portion 267 of the frontside conductive features, the conductive via 240b, the diode contact 225b, the diode 205, the diode contact 225a, the conductive via 240a, the first portion 265 of the frontside conductive features, and the metal feature 308. Components forming the conductive path CP are electrically coupled together. The conductive path CP includes two parts: a first part CP-1 formed by the source/drain feature 214a, the source/drain contact 230, the conductive via 240c, the second portion 267 of the frontside conductive features, the conductive via 240b, the diode contact 225b, the N well 209 of the diode 205; a second part CP-2 formed by the P well 207 of the diode 205, the diode contact 225a, the conductive via 240a, the first portion 265 of the frontside conductive features, and the metal feature 308.

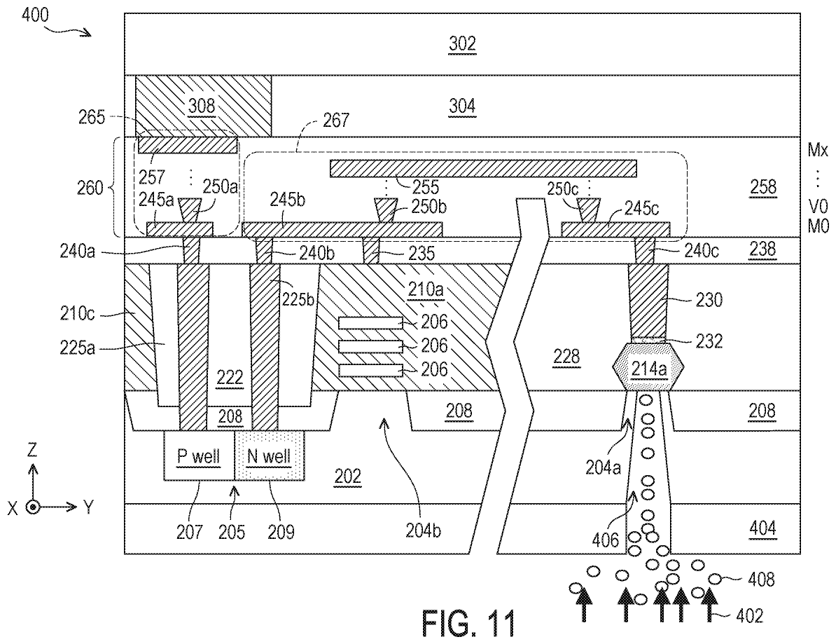

Referring to FIGS. 1 and 11, method 100 includes a block 24 where a first plasma etching process 402 is performed to a back side of the workpiece 200 to form a second trench 406 exposing the source/drain feature 214a. In some embodiments, a hard mask 404 with an opening is formed below the workpiece 200. While using the hard mask 404 as an etch mask, the first plasma etching process 402 is performed to remove a portion of the substrate 202 to form the second trench 406. At least a portion of a bottom surface of the source/drain feature 214a is exposed in the second trench 406. The hard mask 404 may be then selectively removed after forming the second trench 406. During the first plasma etching process 402, electrical charges 408 (e.g., electrons) may be generated and may flow into the workpiece 200 from the opening of the hard mask 404 as shown in FIG. 11. As the workpiece 200 is etched, at least some of the electrical charges 408 may be discharged via the conductive path CP to the carrier substrate 302. Electrical charges 408 in the workpiece 200, if any, travel via the conductive path CP, instead of accumulating in the workpiece 200 (e.g., accumulating in the gate via 235, the metal gate structure 210a, and the channel layers 206), thereby preventing components of the transistor T1 (e.g., the metal gate structure 210a, the channel layers 206) from being damaged during the first plasma etching process 402. In embodiments, the transistor T1 (e.g., including the metal gate structure 210a and the channel layers 206 wrapped by the metal gate structure 210a) and the gate via 235 are free of the electrical charges 408 during the first plasma etching process 402. In some embodiments, the carrier substrate 302 is grounded during the performing of the first plasma etching process 402 and the electrical charges 408 are released.

The conductive path CP provides an electrical discharge path for the electrical charges 408 generated during an etching process (e.g., the first plasma etching process 402). The conductive path CP can minimize etching damage, such as PID damage, reduce area required for the protection circuit, reduce (or eliminate) impact on performance of the devices (e.g., the transistor T1) of the workpiece 200, and/or enhance an etching process window available for etching the workpiece 200 to form backside conductive features (since the conductive path CP can effectively discharge etching-induced charges, thereby improving the tolerance of the processing (for example, allowing a higher power plasma environment)) of the semiconductor structure. Besides providing an electrical discharge path for charge generated during the etching process, such as charge generated during the plasma etching process, the conductive path CP may also serve as an electrical discharge path for charges generated during other fabrication processes and/or operation of the semiconductor structure, particularly, charge induced during any plasma environment processes (e.g., plasma enhanced ALD (PEALD) process, plasma enhanced CVD (PECVD) process).

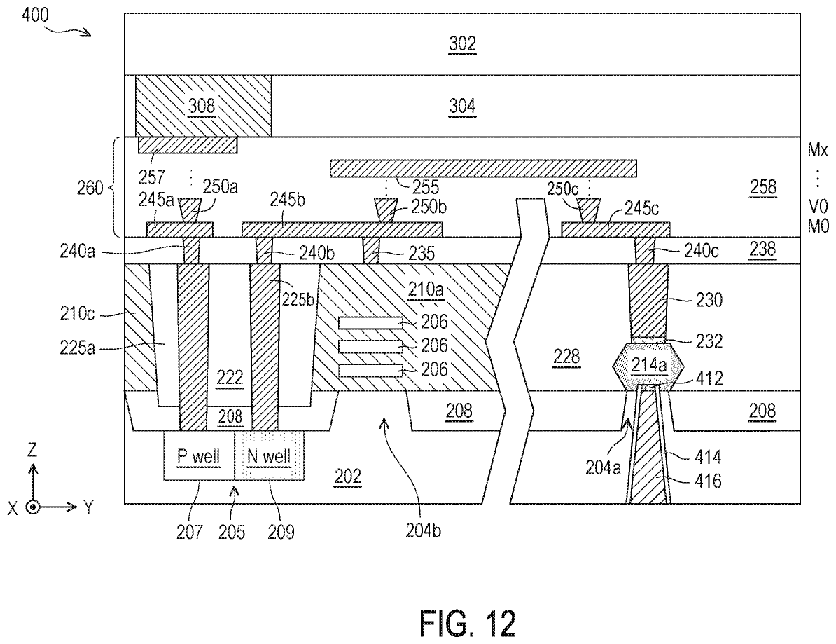

Referring to FIGS. 1 and 12, method 100 includes a block 26 where a backside via 416 (or a first backside conductive feature 416) is formed in the second trench 406 and electrically coupled to the source/drain feature 214a. In embodiments, the conductive path CP is further formed by the backside via 416.

In embodiments, the backside via 416 is spaced apart from the substrate 202 by a dielectric liner 414. The dielectric liner 414 may include a dielectric material such as silicon oxide, silicon nitride, silicon carbide, silicon oxynitride, SiCN films, silicon oxycarbide, SiOCN films, and/or combinations thereof. By way of example, the dielectric liner 414 may be formed by blanket depositing a dielectric material layer in a conformal manner over the backside of the workpiece 200 using processes such as, a CVD process, a sub-atmospheric CVD (SACVD) process, an ALD process, a PVD process, or other suitable process. In the illustrated embodiment, the deposition of the dielectric material layer is followed by an etching-back (e.g., anisotropically) process to remove the dielectric material layer from horizontal surfaces and expose the bottom surface of the S/D feature 214a. The dielectric material layer may remain on the sidewalls of the second trench 406 as the dielectric liner 414. In some embodiments, the etching-back process may include a wet etch process, a dry etch process, a multiple-step etch process, and/or a combination thereof.

In embodiments, the backside via 416 is then disposed in the second trench 406 over the dielectric liner 414. The backside via 416 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. The dielectric liner 414 provides electrical isolation between the backside via 416 and substrate 202. In one embodiment, a backside silicide feature 412 is formed between the S/D features 214a and the backside via 416 to further reduce contact resistance. Forming the backside silicide feature 412 may include depositing one or more metals into the second trench 406, performing an annealing process to the workpiece 200 to cause reaction between the one or more metals and the S/D feature 214a to produce the backside silicide feature 412, and removing un-reacted portions of the one or more metals, leaving the backside silicide feature 412 in the second trench 406. In cases the backside silicide feature 412 is formed, the conductive path CP is further formed by the backside silicide feature 412. The one or more metals may include titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals) and may be deposited using CVD, PVD, ALD, or other suitable methods. The backside silicide feature 412 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. A planarization operation, such as a CMP process, is performed to remove excessive materials of the backside via 416 and the dielectric liner 414. Alternatively, the backside via 416 directly contacts the S/D features 214a.

In the present embodiments, the backside via 416 extends through the substrate 202. In some other embodiments, after the carrier piece 300 is bonded with the workpiece 200, the substrate 202 below the source/drain feature 214a is replaced with a replacement dielectric layer (not depicted), the second trench 406 is formed by etching through (e.g., by the first plasma etching process 402) the replacement dielectric layer to expose the source/drain feature 214a, and the backside via 416 is formed in the second trench 406. In such embodiments, the dielectric liner 414 may be omitted.

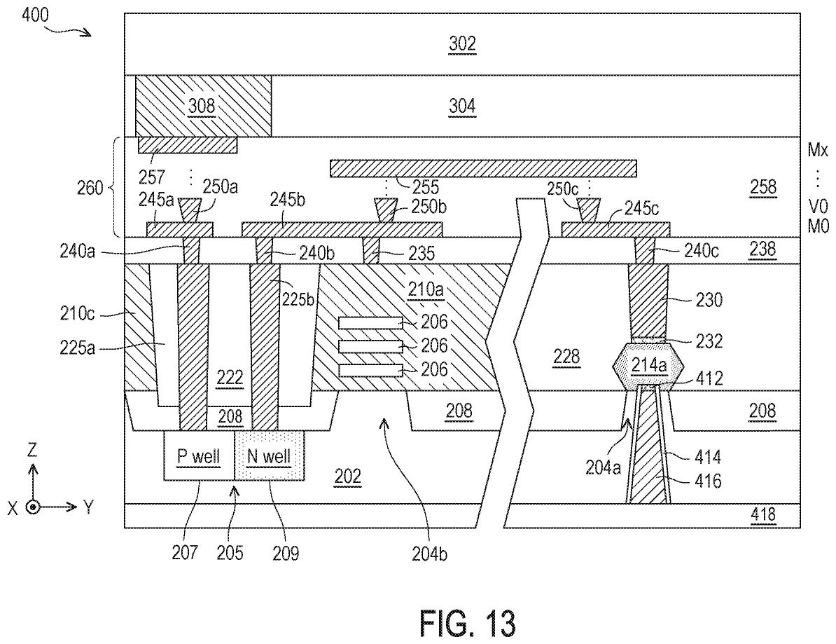

Referring to FIGS. 1 and 13, method 100 includes a block 28 where a dielectric layer 418 is formed below the back side of the workpiece 200. The dielectric layer 418 may include similar dielectric materials as the materials in the dielectric layer 238 and be formed using similar methods as the dielectric layer 238, such as PECVD, FCVD, spin-on coating, or a suitable deposition technique.

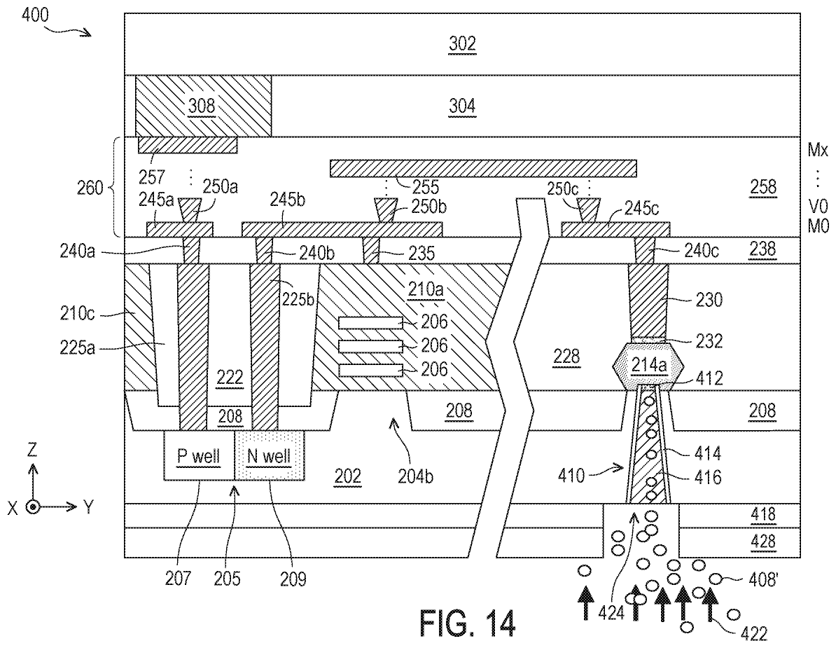

Referring to FIGS. 1 and 14, method 100 includes a block 30 where a second plasma etching process 422 is performed to form a third trench 424 extending through the dielectric layer 418 to expose the backside via 416.

In some embodiments, a hard mask 428 with an opening is formed below the dielectric layer 418. While using the hard mask 428 as an etch mask, the second plasma etching process 422 is performed to remove a portion of the dielectric layer 418 to form the third trench 424. At least a portion of a bottom surface of the backside via 416 is exposed in the third trench 424. The hard mask 428 may be then selectively removed after forming the third trench 424. Similar to the first plasma etching process 402, during the second plasma etching process 422, electrical charges (e.g., electrons) 408′ may be generated and may flow into the workpiece 200 from the opening of the hard mask 428 as shown in FIG. 14. As the dielectric layer 418 is etched, at least some of the electrical charges 408′ may be discharged via the conductive path CP to the carrier substrate 302. Electrical charges 408′ in the workpiece 200, if any, travel via the conductive path CP, instead of accumulating in the workpiece 200 (e.g., accumulating in the gate via 235, the metal gate structure 210a, and the channel layers 206), thereby preventing the components of the transistor T1 (e.g., the metal gate structure 210a, the channel layers 206) from being damaged during the second plasma etching process 422. In embodiments, the transistor T1 (e.g., including the metal gate structure 210a and the channel layers 206 wrapped by the metal gate structure 210a) and the gate via 235 are free of the electrical charges 408 during the second plasma etching process 422. In some embodiments, the carrier substrate 302 is grounded during the performing of the second plasma etching process 422 and the electrical charges 408 are released. Benefits of the conductive path CP during the second plasma etching process 422 are similar to those described above with respect to the first plasma etching process 402.

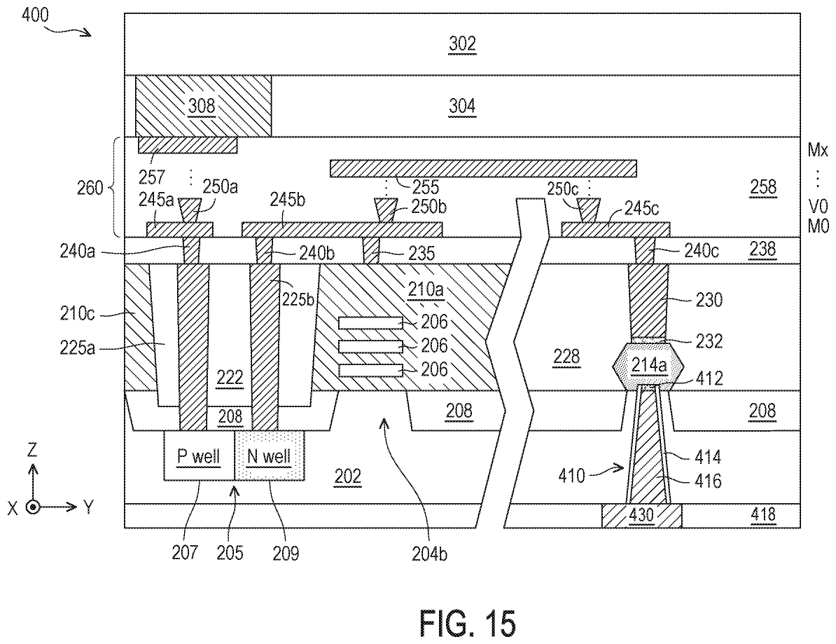

Referring to FIGS. 1 and 15, method 100 includes a block 32 where a second backside conductive feature 430 is formed in the third trench 424. The second backside conductive feature 430 is electrically coupled to the backside via 416, and the conductive path CP is further formed by the second backside conductive feature 430.

The forming of the second backside conductive feature 430 may be similar to the frontside conductive features. For example, the second backside conductive feature 430 may be formed using damascene processes, dual damascene processes, chemical vapor deposition (CVD), physical vapor deposition (PVD), atomic layer deposition (ALD), and/or other suitable processes. A CMP process is then employed to remove excess materials and planarize the top surface. The second backside conductive feature 430 may include similar materials as the frontside conductive features and may include a conductive barrier layer (such as TiN or TaN) surrounding a metal core (such as copper). Although not shown, the second backside conductive feature 430 is electrically isolated from the substrate 202 by an etch stop layer.

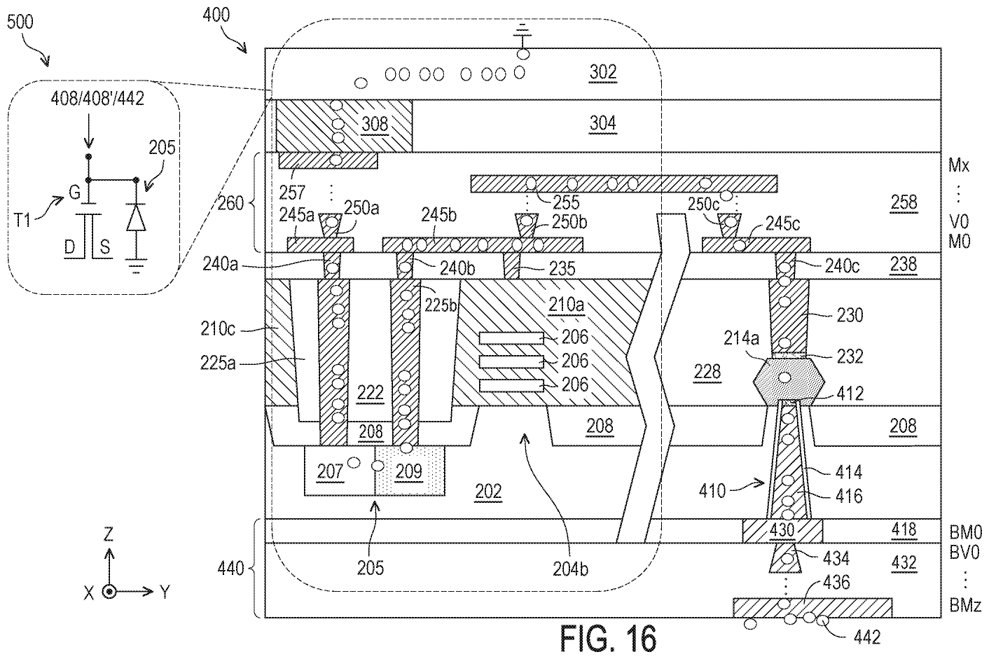

Referring to FIGS. 1 and 16, method 100 includes a block 34 where further processes are performed. For example, additional dielectric layers 432 and additional backside conductive features (e.g., backside conductive features 434 and 436) may be formed to finish the fabrication of a backside interconnect structure 440 by repeating one or more times of similar steps (e.g., blocks 28, 30, and 32) as the dielectric layer 418 and the second backside conductive feature 430, respectively. The additional backside conductive features are electrically coupled to the second backside conductive feature 430. Similarly, electrical charges 442 generated during the formation of the backside conductive features 434 and 436 may also be discharged by the conductive path CP. In some embodiments, the method further includes separating the carrier piece 300 from the workpiece 200 after forming the backside interconnect structure 440.

The dielectric layer 418, the second backside conductive feature 430, the additional dielectric layers 432, and additional backside conductive features (e.g., the backside conductive features 434 and 436) collectively form the backside interconnect structure 440 as shown in FIG. 16. The backside via 416, the second backside conductive feature 430, and the additional backside conductive features collectively form the backside conductive features. The dielectric layer 418 and the additional dielectric layers 432 collectively form a backside dielectric structure. The conductive path CP now includes three parts: the first part CP-1, the second part CP-2, and a third part CP-3 formed by the backside conductive features. The conductive path CP now is formed by the backside conductive features, the source/drain feature 214a, the source/drain contact 230, the conductive via 240c, the second portion 267 of the frontside conductive features, the conductive via 240b, the diode contact 225b, the diode 205, the diode contact 225a, the conductive via 240a, the first portion 265 of the frontside conductive features, and the metal feature 308. In embodiments, the backside conductive features may transfer power supply to the transistors and be referred to as a power rail. In embodiments, the carrier substrate 302 is grounded.

In the depicted embodiment, the backside interconnect structure 440 includes a backside metal zero level BM0 (BM0 level), a backside via zero interconnect layer BV0 (BV0 level), . . . , and a backside metal z interconnect layer BMz (BMz level). Levels between the BV0 level and the BMz level are not shown for simplicity. Each of the BM0 level, BV0 level, . . . , and BMz level may be referred to as a backside metal level. Metal lines formed at the BM0 level may be referred to as BM0 metal lines (e.g., the second backside conductive feature 430). Similarly, via or metal lines formed at the BV0 level and BMz level may be referred to as BV0 vias and BMz metal lines, respectively, z is an integer ranging from 1 to 10. Each level of the backside interconnect structure 440 includes the backside conductive features (e.g., metal lines, metal vias) disposed in one or more dielectric layers (e.g., the dielectric layers 418 and 432).

In embodiments represented by FIG. 16, the BM0 level includes the second backside conductive feature 430. The BV0 level includes the backside conductive feature 434 (or BV0 via 434) disposed in the additional dielectric layers 432 and formed under and electrically coupled to the second backside conductive feature 430. The BMz level includes the backside conductive feature 436 (or BMz metal line 436) disposed in the additional dielectric layers 432, where the BMz metal line 436 is below and electrically coupled to the backside conductive feature 434 (e.g., by metal lines and metal vias in levels BM (z-1) through BM1).

In the above embodiments described with reference to FIGS. 2 and 4-16, the backside via 416 is formed directly under the source/drain feature 214a, and the conductive path CP includes a bypass path (e.g., the CP-2) for transferring the electrical charges generated during the formation of the backside via and/or other conductive features of the backside interconnect structure 440. The positional relationships among the source/drain feature 214a, the metal gate structure 210a, and the diode 205 are merely an example and are not intended to limit the present disclosure to what is explicitly illustrated therein. For example, in some other embodiments, one or more backside vias and/or other conductive features of the backside interconnect structure 440 may be formed under other source/drain features (e.g., the source/drain feature 214e, source/drain features (not depicted) adjacent to the metal gate structure 210c or the metal gate structure 210d), and the electrical charges generated during the formation of those backside vias and/or other conductive features of the backside interconnect structure 440 may also be discharged in a manner similar to that described above with respect to method 100.

Still referring to FIG. 16, an equivalent circuit 500 of a portion of the workpiece 400 is illustrated. The transistor T1 includes a gate structure (G) corresponding to the metal gate structure 210a, and a source feature(S) and a drain feature (D) corresponding to the source/drain features 214b and 214c. When the carrier substrate 302 is grounded, electrical charges (e.g., electrical charges 408, 408′, 442) generated during the plasma etching process (e.g., plasma etching processes 402 and 422) may be discharged by way of the conductive path CP (e.g., the second part CP-2), rather than being accumulated at the gate structure of the transistor T1. The transistor T1 thus is free of electrical charges generated during the plasma etching processes.

It is understood that method 100 described herein can be applied in forming a semiconductor device including multiple of the structures of the workpiece 200, 300, and/or 400 described above and as shown in FIGS. 2-16. In such embodiments, a plurality of conductive paths CP may be formed. A plurality of backside conductive features in a same backside metal interconnect layer (e.g., BM0 level) may be formed simultaneously.

Although not intended to be limiting, one or more embodiments of the present disclosure provide many benefits to a semiconductor structure and the formation thereof. For example, the present disclosure provides a semiconductor structure including a conductive path that can reduce plasma induced damage (PID) during and/or after the manufacturing processes (e.g., plasma etching processes to a back side of the semiconductor structure). The semiconductor structures and methods disclosed herein also reduce area required for the protection circuit, reduce (or eliminate) impact on performance of devices (e.g., a transistor), and/or enhance an etching process window available for etching the semiconductor structure to form backside conductive features. This should not be interpreted as limiting the disclosed semiconductor structures and methods from reducing other types of plasma-induced damage. For example, it is contemplated that the disclosed semiconductor structures and methods can reduce any damage that is induced by processes using a plasma environment. It is understood, however, that other embodiments may offer additional advantages, and not all advantages are necessarily disclosed herein, and that no particular advantage is required for all embodiments.

The present disclosure provides for many different embodiments. Semiconductor structures and methods of fabrication thereof are disclosed herein. In one exemplary aspect, the present disclosure is directed to a method. The method includes providing a workpiece, providing a carrier piece including a carrier substrate and a bonding layer over the carrier substrate, forming a first trench through the bonding layer, and forming a metal feature in the first trench. The workpiece includes a diode in a substrate, a first transistor including a source/drain (S/D) feature in and over the substrate, and an interconnect structure disposed over the substrate. The interconnect structure includes a multi-layer dielectric structure and a plurality of frontside conductive features disposed in the multi-layer dielectric structure. The diode is electrically coupled to the S/D feature by a first part of the plurality of frontside conductive features of the interconnect structure. The method further includes attaching the carrier piece to the interconnect structure, such that the metal feature directly contacts one of the plurality of frontside conductive features. The metal feature is electrically coupled to the diode by a second part of the plurality of frontside conductive features of the interconnect structure. The method further includes performing a first plasma etching process to a back side of the substrate to form a second trench exposing a bottom surface of the S/D feature, and forming a first backside conductive feature in the second trench and electrically coupled to the S/D feature.

In some embodiments, the diode includes a P well and an N well. The workpiece further includes a second transistor adjacent to the diode and including an active region and a metal gate structure disposed over the active region, a gate via disposed over and contacting the metal gate structure, first contacts disposed over the P well and electrically connecting the P well to the second part of the plurality of frontside conductive features of the interconnect structure, second contacts disposed over the N well and electrically connecting the N well to the first part of the plurality of frontside conductive features of the interconnect structure, and third contacts disposed over the S/D feature and electrically connecting the S/D feature to the first part of the plurality of frontside conductive features of the interconnect structure. In some embodiments, a first conductive path electrically coupling the S/D feature and the N well is formed by the second contacts, the third contacts, and the first part of the plurality of frontside conductive features. A second conductive path electrically coupling the P well and the carrier substrate is formed by the first contacts, the second part of the plurality of frontside conductive features, and the metal feature. In some embodiments, the metal gate structure is connected to the first part of the plurality of frontside conductive features by the gate via. In some embodiments, during the performing of the first plasma etching process, the second transistor is free of electrical charges. In some embodiments, a conductive path electrically coupling the carrier substate and the S/D feature is formed by the metal feature, the second part of the plurality of frontside conductive features, the diode, and the first part of the plurality of frontside conductive features. In some embodiments, the method further includes electrically grounding the carrier substrate. In some embodiments, the method further includes forming a dielectric layer below a bottom surface of the workpiece, performing a second plasma etching process to a back side of the workpiece to form a third trench in the dielectric layer, the third trench exposing a bottom surface of the first backside conductive feature, and forming a second backside conductive feature in the third trench. In some embodiments, the workpiece further includes an isolation feature disposed over the diode.

In another exemplary aspect, the present disclosure is directed to a method. The method includes providing a first workpiece and providing a second workpiece. The first workpiece includes a first transistor including a source/drain (S/D) feature, a second transistor adjacent to the first transistor and including a gate structure, a diode adjacent to the second transistor, and an interconnect structure including a plurality of metal lines and vias. A first interconnect layer of the interconnect structure includes a metal line electrically coupled to both the gate structure and the S/D feature. The second workpiece includes a first dielectric layer, a metal feature extending through the first dielectric layer, and a carrier substrate disposed over the first dielectric layer. The method further includes attaching the second workpiece to the first workpiece, such that the metal feature is electrically coupled to the gate structure by the diode and the plurality of metal lines and vias, and performing a first plasma etching process to a back side of the first workpiece to form a first trench. The S/D feature is exposed in the first trench. The method further includes forming a first backside conductive feature in the first trench.

In some embodiments, during the performing of the first plasma etching process, the second transistor is free of electrical charges. In some embodiments, during the performing of the first plasma etching process, a conductive path electrically coupling the S/D feature and the carrier substrate is formed by the plurality of metal lines and vias, the diode, and the metal feature. In some embodiments, the gate structure wraps around a plurality of nanostructures of the second transistor and the first transistor. In some embodiments, the diode includes a P well and an N well laterally adjacent to the N well, and a distance between the N well and the gate structure is less than a distance between the P well and the gate structure. The plurality of metal lines and vias includes a first portion connected to the metal feature and the P well and a second portion connected to each of the N well, the gate structure, and the S/D feature. The first portion is spaced apart from the second portion. In some embodiments, the method further includes electrically grounding the carrier substrate. In some embodiments, the method further includes forming a second dielectric layer below the first backside conductive feature, and performing a second plasma etching process to the back side of the first workpiece to form a second trench through the second dielectric layer. The first backside conductive feature is exposed in the second trench. The method further includes forming a second backside conductive feature in the second trench.

In yet another exemplary aspect, the present disclosure is directed to a semiconductor structure. The semiconductor structure includes a first substrate, a first transistor including a fin structure protruding from the first substrate and a metal gate structure disposed over the fin structure, a diode disposed in the first substrate and adjacent to the first transistor, a second transistor adjacent to the first transistor and including a source/drain (S/D) feature, a first backside conductive structure disposed below and electrically coupled to the S/D feature, and an interconnect structure disposed over the first substrate. The interconnect structure includes a multi-layer dielectric structure and a plurality of frontside conductive features embedded in the multi-layer dielectric structure. The semiconductor structure further includes a dielectric layer disposed over the interconnect structure, a metal feature disposed through the dielectric layer and contacting one of the plurality of frontside conductive features, and a second substrate disposed over the dielectric layer and the metal feature. The plurality of frontside conductive features includes a first portion connected to the metal feature and a P well of the diode, and a second portion connected to the S/D feature, the metal gate structure, and an N well of the diode.

In some embodiments, the semiconductor structure further includes first contacts connecting the P well and the first portion of the plurality of frontside conductive features, second contacts connecting the N well and the second portion of the plurality of frontside conductive features, a gate via connecting the metal gate structure and the second portion of the plurality of frontside conductive features, and third contacts connecting the S/D feature and the second portion of the plurality of frontside conductive features. In some embodiments, the semiconductor structure further includes a second backside conductive structure below and contacting the first backside conductive structure. In some embodiments, the first backside conductive structure includes a plurality of backside metal lines and backside vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a workpiece comprising:
a diode in a substrate,
a first transistor comprising a source/drain (S/D) feature in and over the substrate, and
an interconnect structure disposed over the substrate and comprising a multi-layer dielectric structure and a plurality of frontside conductive features disposed in the multi-layer dielectric structure, wherein the diode is electrically coupled to the S/D feature by a first part of the plurality of frontside conductive features of the interconnect structure;
providing a carrier piece comprising a carrier substrate and a bonding layer over the carrier substrate;
forming a first trench through the bonding layer;
forming a metal feature in the first trench;
attaching the carrier piece to the interconnect structure, such that the metal feature directly contacts one of the plurality of frontside conductive features, wherein the metal feature is electrically coupled to the diode by a second part of the plurality of frontside conductive features of the interconnect structure;
performing a first plasma etching process to a back side of the substrate to form a second trench exposing a bottom surface of the S/D feature; and
forming a first backside conductive feature in the second trench and electrically coupled to the S/D feature.

2. The method of claim 1, wherein the diode comprises a P well and an N well, and
wherein the workpiece further comprises:
a second transistor adjacent to the diode and comprising an active region and a metal gate structure disposed over the active region,
a gate via disposed over and contacting the metal gate structure,
first contacts disposed over the P well and electrically connecting the P well to the second part of the plurality of frontside conductive features of the interconnect structure,
second contacts disposed over the N well and electrically connecting the N well to the first part of the plurality of frontside conductive features of the interconnect structure, and
third contacts disposed over the S/D feature and electrically connecting the S/D feature to the first part of the plurality of frontside conductive features of the interconnect structure.

3. The method of claim 2, wherein a first conductive path electrically coupling the S/D feature and the N well is formed by the second contacts, the third contacts, and the first part of the plurality of frontside conductive features, and
wherein a second conductive path electrically coupling the P well and the carrier substrate is formed by the first contacts, the second part of the plurality of frontside conductive features, and the metal feature.

4. The method of claim 2, wherein the metal gate structure is connected to the first part of the plurality of frontside conductive features by the gate via.

5. The method of claim 2, wherein during the performing of the first plasma etching process, the second transistor is free of electrical charges.

6. The method of claim 1, wherein a conductive path electrically coupling the carrier substate and the S/D feature is formed by the metal feature, the second part of the plurality of frontside conductive features, the diode, and the first part of the plurality of frontside conductive features.

7. The method of claim 1, further comprising electrically grounding the carrier substrate.

8. The method of claim 1, further comprising:
forming a dielectric layer below a bottom surface of the workpiece;
performing a second plasma etching process to a back side of the workpiece to form a third trench in the dielectric layer, the third trench exposing a bottom surface of the first backside conductive feature; and
forming a second backside conductive feature in the third trench.

9. The method of claim 1, wherein the workpiece further comprises an isolation feature disposed over the diode.

10. A method, comprising:
providing a first workpiece comprising:
a first transistor comprising a source/drain (S/D) feature,
a second transistor adjacent to the first transistor and comprising a gate structure,
a diode adjacent to the second transistor, and
an interconnect structure comprising a plurality of metal lines and vias, wherein a first interconnect layer of the interconnect structure comprises a metal line electrically coupled to both the gate structure and the S/D feature;
providing a second workpiece comprising:
a first dielectric layer,
a metal feature extending through the first dielectric layer, and
a carrier substrate disposed over the first dielectric layer;
attaching the second workpiece to the first workpiece, such that the metal feature is electrically coupled to the gate structure by the diode and the plurality of metal lines and vias;
performing a first plasma etching process to a back side of the first workpiece to form a first trench, wherein the S/D feature is exposed in the first trench; and
forming a first backside conductive feature in the first trench.

11. The method of claim 10, wherein during the performing of the first plasma etching process, the second transistor is free of electrical charges.

12. The method of claim 10, wherein during the performing of the first plasma etching process, a conductive path electrically coupling the S/D feature and the carrier substrate is formed by the plurality of metal lines and vias, the diode, and the metal feature.

13. The method of claim 10, wherein the gate structure wraps around a plurality of nanostructures of the second transistor and the first transistor.

14. The method of claim 10, wherein the diode comprises a P well and an N well laterally adjacent to the N well, and a distance between the N well and the gate structure is less than a distance between the P well and the gate structure,
wherein the plurality of metal lines and vias comprises a first portion connected to the metal feature and the P well and a second portion connected to each of the N well, the gate structure, and the S/D feature, and
wherein the first portion is spaced apart from the second portion.

15. The method of claim 10, further comprising electrically grounding the carrier substrate.

16. The method of claim 10, further comprising:
forming a second dielectric layer below the first backside conductive feature;
performing a second plasma etching process to the back side of the first workpiece to form a second trench through the second dielectric layer, wherein the first backside conductive feature is exposed in the second trench; and
forming a second backside conductive feature in the second trench.

17. A semiconductor structure, comprising:
a first substrate;
a first transistor comprising a fin structure protruding from the first substrate and a metal gate structure disposed over the fin structure;
a diode disposed in the first substrate and adjacent to the first transistor;
a second transistor adjacent to the first transistor and comprising a source/drain (S/D) feature;
a first backside conductive structure disposed below and electrically coupled to the S/D feature;
an interconnect structure disposed over the first substrate, wherein the interconnect structure comprises a multi-layer dielectric structure and a plurality of frontside conductive features embedded in the multi-layer dielectric structure;
a dielectric layer disposed over the interconnect structure;
a metal feature disposed through the dielectric layer and contacting one of the plurality of frontside conductive features; and
a second substrate disposed over the dielectric layer and the metal feature,
wherein the plurality of frontside conductive features comprises a first portion connected to the metal feature and a P well of the diode, and a second portion connected to the S/D feature, the metal gate structure, and an N well of the diode.

18. The semiconductor structure of claim 17, further comprising:
first contacts connecting the P well and the first portion of the plurality of frontside conductive features,
second contacts connecting the N well and the second portion of the plurality of frontside conductive features,
a gate via connecting the metal gate structure and the second portion of the plurality of frontside conductive features, and
third contacts connecting the S/D feature and the second portion of the plurality of frontside conductive features.

19. The semiconductor structure of claim 17, further comprising a second backside conductive structure below and contacting the first backside conductive structure.

20. The semiconductor structure of claim 17, wherein the first backside conductive structure comprises a plurality of backside metal lines and backside vias.
